(19) United States
(12) Patent Application Publication
(10) Pub. No.: US 2025/0157890 A1
(43) Pub. Date: May 15, 2025

(54) SEMICONDUCTOR DEVICE

(71) Applicant: Japan Display Inc., Tokyo (JP)

(72) Inventors: Takamitsu FUJIMOTO, Tokyo (JP); Kenji HARADA, Tokyo (JP); Takayuki SUZUKI, Tokyo (JP)

(73) Assignee: Japan Display Inc., Tokyo (JP)

(21) Appl. No.: 18/945,958

(22) Filed: Nov. 13, 2024

(30) Foreign Application Priority Data
Nov. 15, 2023 (JP) 2023-194160

(51) Int. Cl. H01L 23/48; H01L 27/092; H01L 29/423

(52) U.S. Cl. CPC H01L 23/481; H10D 64/518; H10D 64/519; H10D 84/85

(57) ABSTRACT

A semiconductor device according to an embodiment of the present invention includes: a first semiconductor layer; a first gate electrode facing the first semiconductor layer; a second gate electrode facing the first semiconductor layer and supplied with the same voltage as the first gate electrode; a first gate insulating layer between the first semiconductor layer and the first gate electrode, and between the first semiconductor layer and the second gate electrode; a second semiconductor layer sandwiching the first gate electrode with the first semiconductor layer; a third gate electrode facing the second semiconductor layer on an opposite side to the first gate electrode with respect to the second semiconductor layer, and overlapping the first gate electrode in a plan view; and a second gate insulating layer between the second semiconductor layer and the third gate electrode.

### CROSS REFERENCE TO RELATED APPLICATIONS

This application claims the benefit of priority to Japanese Patent Application No. 2023-194160, filed on Nov. 15, 2023, the entire contents of which are incorporated herein by reference.

### FIELD

An embodiment of the present invention relates to a semiconductor device.

### BACKGROUND

In recent years, a semiconductor device including a transistor in which different semiconductor materials are formed on the same substrate as a semiconductor layer has been developed. For example, a transistor using a polysilicon is used for a transistor requiring high-speed operation, and a transistor using an oxide semiconductor is used for a transistor requiring a switching operation with low leakage current in an off-state, so that transistors with different characteristics due to the required function can be formed on the same substrate. Japanese laid-open patent publication No. 2018-128693 discloses a display device in which a transistor in which a silicon is used for a driving circuit in a peripheral region is formed, and a transistor in which an oxide semiconductor is used for a pixel circuit in a display region is formed on the same substrate.

### SUMMARY

A semiconductor device according to an embodiment of the present invention includes: a first semiconductor layer; a first gate electrode facing the first semiconductor layer; a second gate electrode facing the first semiconductor layer and supplied with the same voltage as the first gate electrode; a first gate insulating layer between the first semiconductor layer and the first gate electrode, and between the first semiconductor layer and the second gate electrode; a second semiconductor layer sandwiching the first gate electrode with the first semiconductor layer; a third gate electrode facing the second semiconductor layer on an opposite side to the first gate electrode with respect to the second semiconductor layer, and overlapping the first gate electrode in a plan view; and a second gate insulating layer between the second semiconductor layer and the third gate electrode.

### BRIEF DESCRIPTION OF DRAWINGS

FIG. 1 is a cross-sectional view illustrating a semiconductor device according to an embodiment of the present invention.

FIG. 2 is a circuit configuration of a semiconductor device according to an embodiment of the present invention.

FIG. 3 is a plan view illustrating a semiconductor device according to an embodiment of the present invention.

FIG. 4 is a cross-sectional view illustrating a semiconductor device according to an embodiment of the present invention.

FIG. 5 is a cross-sectional view illustrating a method for manufacturing a semiconductor device according to an embodiment of the present invention.

FIG. 6 is a cross-sectional view illustrating a method for manufacturing a semiconductor device according to an embodiment of the present invention.

FIG. 7 is a cross-sectional view illustrating a method for manufacturing a semiconductor device according to an embodiment of the present invention.

FIG. 8 is a cross-sectional view illustrating a method for manufacturing a semiconductor device according to an embodiment of the present invention.

### DESCRIPTION OF EMBODIMENTS

Hereinafter, embodiments of the present invention will be described with reference to the drawings. The following disclosures are merely examples. A configuration that can be easily conceived by a person skilled in the art by appropriately changing the configuration of the embodiment while keeping the gist of the invention is naturally included in the scope of the present invention. For clarity of explanation, the drawings may be schematically represented with respect to widths, thicknesses, shapes, and the like of respective portions as compared with actual embodiments. However, the illustrated shapes are merely examples, and do not limit the interpretation of the present invention. In the present specification and the drawings, the same reference signs are given to the same components as those described above with respect to the above-described drawings, and detailed description thereof may be omitted as appropriate.

In each embodiment of the present invention, a direction from a substrate toward a semiconductor layer is referred to as on or above. Conversely, a direction from the semiconductor layer toward the substrate is referred to as under or below. In this way, for convenience of explanation, although the phrase “above” or “below” is used for description, for example, a vertical relationship between the substrate and the semiconductor layer may be different from that shown in the drawings. In the following explanation, for example, the expression “semiconductor layer on a substrate” merely describes the vertical relationship between the substrate and the semiconductor layer as described above, and another member may be arranged between the substrate and the semiconductor layer. Above or below means a stacking order in a structure in which a plurality of layers is stacked, and when expressed as a second member above a first member, the first member and the second may be in a positional relationship in which they do not overlap in a plan view. On the other hand, the second member vertically above the first member indicates a positional relationship in which the first member and the second member overlap in a plan view.

In the present specification, expressions such as “a includes A, B, or C,” “a includes any of A, B, and C,” and “α includes one selected from a group consisting of A, B, and C do not exclude the case where α includes a plurality of combinations of A to C unless otherwise specified. Furthermore, these expressions do not exclude the case where α includes other elements.

In addition, each configuration can be combined with each other as long as there is no technical contradiction.

An object of an embodiment of the present invention is to provide a semiconductor device having good electric characteristics and high reliability for each of the transistors having different characteristics.

### [1. Cross-Sectional Structure of Semiconductor Device]

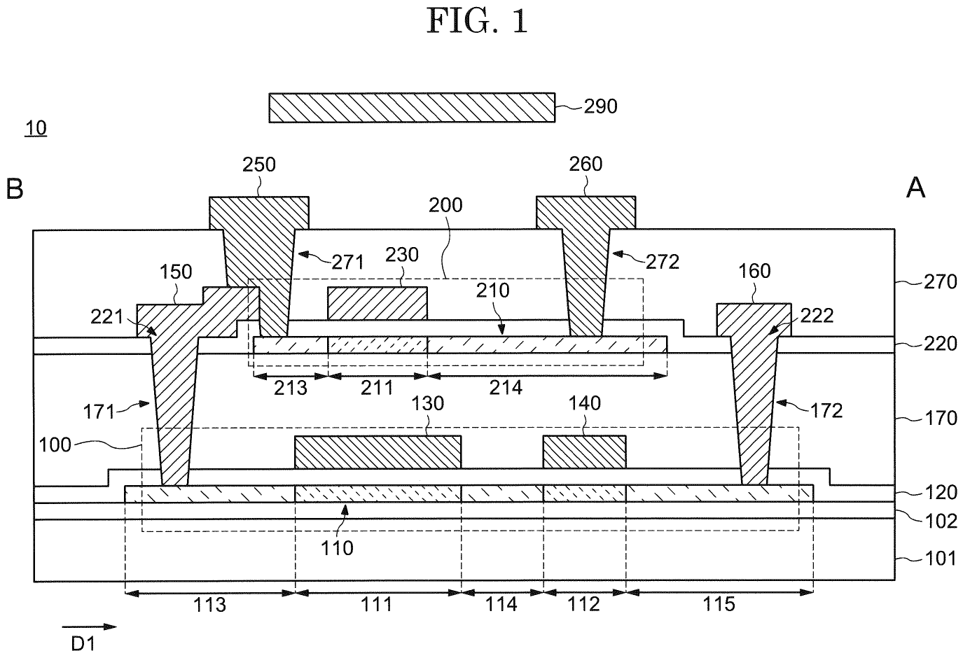

An example of a structure of a semiconductor device 10 according to an embodiment of the present invention will be described with reference to FIG. 1 to FIG. 3. FIG. 1 is a cross-sectional view of the semiconductor device 10 according to an embodiment of the present invention. As shown in FIG. 1, the semiconductor device 10 according to an embodiment of the present invention includes a transistor 100 arranged on a substrate 101 and a transistor 200 arranged above the transistor 100.

Either an N-type transistor or a P-type transistor may be used as the transistor 100. In the present embodiment, an example in which a top-gate type and the P-type transistor in which a polysilicon is used for a semiconductor layer is used as the transistor 100 will be described.

Either the N-type transistor or the P-type transistor may be used as the transistor 200. In the present embodiment, an example in which a dual-gate type and the N-type transistor in which an oxide semiconductor is used for the semiconductor layer is used as the transistor 200 will be described.

In the present embodiment, the transistor 100 is the P-type transistor, and the transistor 200 is the N-type transistor. Therefore, the semiconductor device 10 constitutes a Complementary Metal-Oxide-Semiconductor (CMOS) circuit. However, an embodiment of the present invention is not limited to the above-described CMOS circuit. For example, the transistor 100 may be the N-type transistor, and the transistor 200 may be the P-type transistor. Alternatively, an embodiment of the present invention may not be the CMOS circuit. That is, both of the transistors 100 and 200 may be the N-type transistors or the P-type transistors.

### [1-1. Structure of Transistor 100]

The transistor 100 includes a semiconductor layer 110, a gate insulating layer 120, gate electrodes 130 and 140, and electrodes 150 and 160. An insulating layer 102 is arranged on the substrate 101. The insulating layer 102 suppresses impurities contained in the substrate 101 from diffusing into the semiconductor layer 110. That is, the insulating layer 102 has barrier properties.

The semiconductor layer 110 is arranged on the insulating layer 102. The semiconductor layer 110 is divided into channel regions 111 and 112 and low resistance regions 113 to 115. An impurity (dopant) is implanted into the semiconductor layer 110 in the low resistance regions 113 to 115. A carrier is generated in the semiconductor layer 110 by the dopant. The semiconductor layer 110 in the channel regions 111 and 112 contains no dopant or a small amount of dopant. That is, a dopant concentration in the low resistance regions 113 to 115 is higher than a dopant concentration in the channel regions 111 and 112. In the case where a material used for the semiconductor layer 110 is silicon and the transistor 100 is the P-type transistor, boron is used as the dopant. On the other hand, in the case where the transistor 100 is the N-type transistor, phosphorus is used as the dopant.

The gate electrodes 130 and 140 face the semiconductor layer 110. Specifically, the gate electrode 130 faces the semiconductor layer 110 in the channel region 111. The gate electrode 140 faces the semiconductor layer 110 in the channel region 112. The gate insulating layer 120 is arranged between the gate electrode 130 and the semiconductor layer 110 and between the gate electrode 140 and the semiconductor layer 110. The gate electrode 130 and the gate electrode 140 are arranged in the same layer. That is, the gate electrode 130 and the gate electrode 140 are in contact with the gate insulating layer 120. In a direction D1 from the electrode 150 toward the electrode 160, a length of the gate electrode 140 is smaller than a length of the gate electrode 130. Although details will be described later, the gate electrode 130 is connected to the gate electrode 140. The same voltage as the gate electrode 130 is supplied to the gate electrode 140.

The channel regions 111 and 112 and the low resistance regions 113 to 115 are arranged between the electrode 150 and the electrode 160 in the order of the low resistance region 113, the channel region 111, the low resistance region 114, the channel region 112, and the low resistance region 115. The electrode 150 is connected to the low resistance region 113 and the electrode 160 is connected to the low resistance region 115, but no electrode is connected to the low resistance region 114. Therefore, in the case where the channel regions 111 and 112 are both in an off-state, the low resistance region 114 is floating. As described above, the transistor 100 is controlled to be in an on state or off state by the two gate electrodes 130 and 140. That is, the transistor 100 has a double-gate structure.

In the above configuration, the semiconductor layer 110 may be referred to as a “first semiconductor layer”, the gate electrode 130 may be referred to as a “first gate electrode”, the gate electrode 140 may be referred to as a “second gate electrode”, and the gate insulating layer 120 may be referred to as a “first gate insulating layer”. In this case, it can be said that the first gate electrode (the gate electrode 130) and the second gate electrode (the gate electrode 140) face the first semiconductor layer (the semiconductor layer 110). It can be said that the same voltage as the first gate electrode (the gate electrode 130) is supplied to the second gate electrode (the gate electrode 140). The first gate insulating layer (the gate insulating layer 120) may be arranged between the first semiconductor layer (the semiconductor layer 110) and the first gate electrode (the gate electrode 130) and between the first semiconductor layer (the semiconductor layer 110) and the second gate electrode (the gate electrode 140).

Although details will be described later, the channel region 111 overlaps the gate electrode 130 and the channel region 112 overlaps the gate electrode 140 in a plan view. However, the transistor 100 is not limited to the above-described configuration. For example, part of the low resistance regions 113 to 115 may overlap the gate electrodes 130 and 140 in a plan view.

A Lightly Doped Drain (LDD) region may be arranged between the channel regions 111 and 112 and the low resistance regions 113 to 115. A dopant concentration in the LDD region is higher than the dopant concentration in the channel regions 111 and 112 and lower than the dopant concentration in the low resistance regions 113 to 115. The LDD region is arranged between the low resistance region 113 and the channel region 111, between the low resistance region 114 and the channel region 111, between the low resistance region 114 and the channel region 112, and between the low resistance region 115 and the channel region 112.

An insulating layer 170 is arranged on the gate insulating layer 120 and the gate electrodes 130 and 140. Openings 171 and 172 are arranged in the insulating layer 170. The opening 171 is an opening that reaches the semiconductor layer 110 in the low resistance region 113. The opening 172 is an opening that reaches the semiconductor layer 110 in the low resistance region 115.

The electrode 150 is arranged inside the opening 171 and is in contact with the semiconductor layer 110 in the low resistance region 113. The electrode 160 is arranged inside the opening 172 and is in contact with the semiconductor layer 110 in the low resistance region 115.

### [1-2. Structure of Transistor 200]

The transistor 200 includes a semiconductor layer 210, a gate insulating layer 220, a gate electrode 230, and electrodes 250 and 260.

The semiconductor layer 210 is arranged on the insulating layer 170. The semiconductor layer 210 is divided into a channel region 211 and low resistance regions 213 and 214. A dopant is implanted into the semiconductor layer 210 in the low resistance regions 213 and 214. A carrier is generated in the semiconductor layer 210 by the dopant. The semiconductor layer 210 in the channel region 211 contains no dopant or a small amount of dopant. That is, a dopant concentration in the low resistance regions 213 and 214 is higher than the dopant concentration in the channel region 211. In the case where a material used for the semiconductor layer 210 is an oxide semiconductor, phosphorus, boron, argon, or the like is used as the dopant.

In the case where an oxide semiconductor having a polycrystalline structure, which will be described later, is used as the semiconductor layer 210, a sheet resistance in the low resistance region can be lower than that of a conventional oxide semiconductor having an amorphous structure. For example, a sheet resistance of an oxide semiconductor layer in the low resistance regions 213 and 214 is 1000 Ω/sq. or less, preferably 500 Ω/sq. or less, and more preferably 250 Ω/sq. or less.

The gate electrode 230 faces the semiconductor layer 210. Specifically, the gate electrode 230 faces the semiconductor layer 210 in the channel region 211. The gate insulating layer 220 is arranged between the gate electrode 230 and the semiconductor layer 210. The gate electrode 230 is formed in the same layer as the electrodes 150 and 160. That is, the gate electrode 230 and the electrodes 150 and 160 are in contact with an upper surface of the gate insulating layer 220. Openings 221 and 222 are arranged in the gate insulating layer 220 at positions corresponding to the openings 171 and 172. The electrode 150 is arranged inside the opening 221. The electrode 160 is arranged inside the opening 222.

Although details will be described later, the gate electrode 230 is electrically connected to the gate electrode 130. That is, the same voltage as the gate electrode 130 is supplied to the gate electrode 230. In the direction D1, a length of the gate electrode 230 is smaller than the length of the gate electrode 130.

In the above configuration, the semiconductor layer 210 may be referred to as a “second semiconductor layer”, the gate electrode 230 may be referred to as a “third gate electrode”, and the gate insulating layer 220 may be referred to as a “second gate insulating layer”. In this case, it can be said that the second semiconductor layer (the semiconductor layer 210) sandwiches the first gate electrode (the gate electrode 130) together with the first semiconductor layer (the semiconductor layer 110). It can be said that the third gate electrode (the gate electrode 230) faces the second semiconductor layer (the semiconductor layer 210) on the other side of the first gate electrode (130) with respect to the second semiconductor layer (the semiconductor layer 210). It can be said that the second gate insulating layer (the gate insulating layer 220) is arranged between the second semiconductor layer (the semiconductor layer 210) and the third gate electrode (the gate electrode 230).

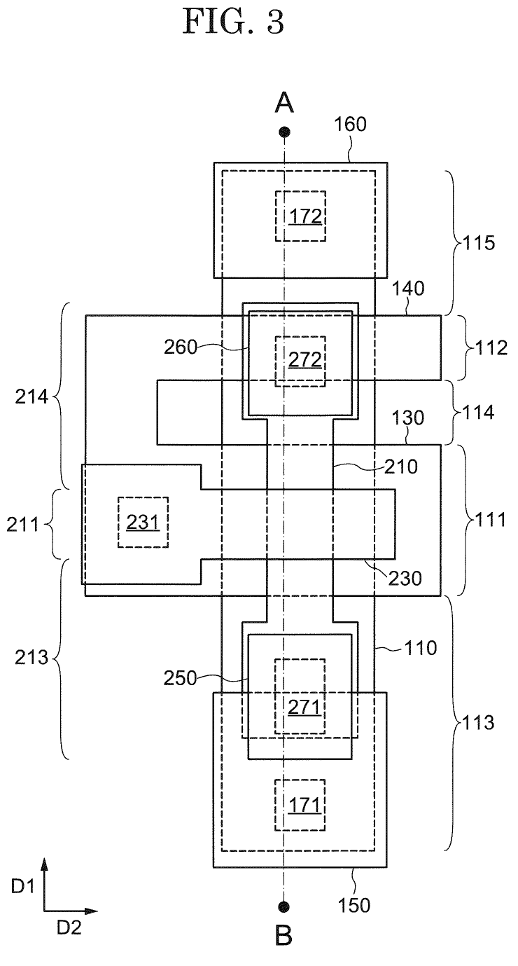

In the above configuration, the electrode 150 may be referred to as a “first electrode”, and the electrode 160 may be referred to as a “second electrode”. The low resistance region 113 may be referred to as a “first region” and the low resistance region 115 may be referred to as a “second region.” In this case, it can be said that the first electrode (the electrode 150) is connected to the first region (the low resistance region 113) of the first semiconductor layer (the semiconductor layer 110). It can be said that the second electrode (the electrode 160) is connected to the second region (the low resistance region 115) of the first semiconductor layer (the semiconductor layer 110) on the other side of the first electrode (the electrode 150) with respect to the first gate electrode (the gate electrode 130) and the second gate electrode (the gate electrode 140). Furthermore, it can be said that in a cross-sectional view (cross-sectional diagram shown in FIG. 1) along a line (line A-B in FIG. 3) connecting the first region (the low resistance region 113) and the second region (the low resistance region 115), the first gate electrode (the gate electrode 130) and the second gate electrode (the gate electrode 140) are separated from each other.

In the above configuration, the electrode 250 may be referred to as a “third electrode”, and the electrode 260 may be referred to as a “fourth electrode”. The low resistance region 213 may be referred to as a “third region” and the low resistance region 214 may be referred to as a “fourth region.” In this case, it can be said that the third electrode (the electrode 250) is connected to the third region (the low resistance region 213) of the second semiconductor layer (the semiconductor layer 210). It can be said that the fourth electrode (the electrode 260) is connected to the fourth region (the low resistance region 214) of the second semiconductor layer (the semiconductor layer 210) on the other side of the third electrode (the electrode 250) with respect to the third gate electrode (the gate electrode 230). It can be said that different voltages are supplied to the second electrode (the electrode 160) and the fourth electrode (the electrode 260). It can be said that the first electrode (the electrode 150) and the third electrode (the electrode 250) are electrically connected to each other. It can be said that the first electrode (the electrode 150) and the third gate electrode (the gate electrode 230) are in the same layer.

Although details will be described later, the channel region 211 overlaps the gate electrode 230 in a plan view. However, the transistor 200 is not limited to the above-described configuration. For example, part of the low resistance regions 213 and 214 may overlap the gate electrode 230 in a plan view.

An insulating layer 270 is arranged on the gate insulating layer 220 and the gate electrode 230. The insulating layer 270 is provided with openings 271 and 272. The opening 271 is an opening that reaches an upper surface of the electrode 150 and the semiconductor layer 210 in the low resistance region 213. Although details will be described later, the opening 271 overlaps a pattern end of the electrode 150 in a plan view. The opening 272 is an opening that reaches the semiconductor layer 210 in the low resistance region 214.

The electrode 250 is arranged on an upper surface of the insulating layer 270 and inside the opening 271 and is in contact with the upper surface of the electrode 150 and the semiconductor layer 210 in the low resistance region 213. Since the pattern end of the electrode 150 is exposed by the opening 271, the electrode 250 is in contact with the pattern end. The electrode 260 is arranged on the upper surface of the insulating layer 270 and inside the opening 272 and is in contact with the semiconductor layer 210 in the low resistance region 214.

A light-shielding layer 290 is arranged on the transistor 200. The light-shielding layer 290 is arranged in a region that covers at least the channel region 211 in a plan view. The light-shielding layer 290 suppresses external light incident on the semiconductor device 10 from above from reaching the semiconductor layer 210 in the channel region 211. External light incident on the semiconductor device 10 from below is blocked by the gate electrode 130, but a light-shielding layer similar to the light-shielding layer 290 may be arranged below the transistor 100.

In the present embodiment, the semiconductor device 10 constitutes the CMOS circuit including the P-type transistor 100 and the N-type transistor 200. A voltage Vdd is supplied to the electrode 160 of the transistor 100. A voltage Vss is supplied to the electrode 260 of the transistor 200. An input signal IN is supplied to the gate electrodes 130 and 140 of the transistor 100 and the gate electrode 230 of the transistor 200, and an output signal OUT corresponding to the input signal IN is output from the electrode 250 of the transistor 200 and/or the electrode 150 of the transistor 100.

### [2. Circuit Configuration of Semiconductor Device]

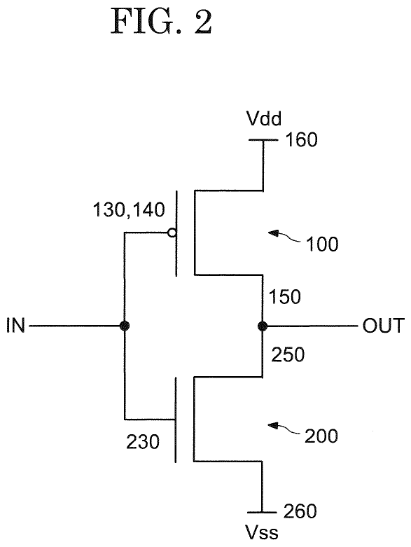

FIG. 2 is a circuit configuration of a semiconductor device according to an embodiment of the present invention. As shown in FIG. 2, the transistor 100 and the transistor 200 are connected in series between the voltage Vdd and the voltage Vss. The gate electrodes 130 and 140 of the transistor 100 are connected to the gate electrode 230 of the transistor 200, and the same input signal IN is supplied to these gate electrodes. The output signal OUT is output from a node (the electrodes 150 and 250) between the transistor 100 and the transistor 200.

### [3. Planar Layout of Semiconductor Device]

FIG. 3 is a plan view illustrating a semiconductor device according to an embodiment of the present invention. The cross-sectional view shown in FIG. 1 is a cross-sectional view cut along a line A-B in FIG. 3. A layout of the transistors 100 and 200 will be described with reference to the plan view shown in FIG. 3.

The semiconductor layer 110 has a longitudinal direction in the direction D1 along which the line A-B extends. The gate electrode 130 and the gate electrode 140 cross the semiconductor layer 110 in a direction D2. The gate electrode 130 is connected to the gate electrode 140 in a region that does not overlap the semiconductor layer 110 in a plan view. The direction D2 is a direction intersecting the direction D1. In the example of FIG. 1, the direction D2 is perpendicular to the direction D1. However, the direction D2 may not be perpendicular to the direction D1.

Among the regions of the semiconductor layer 110, a region that overlaps the gate electrode 130 in a plan view is the channel region 111, and a region that overlaps the gate electrode 140 in a plan view is the channel region 112. On the other hand, a region of the semiconductor layer 110 that does not overlap any of the gate electrodes 130 and 140 in a plan view is the low resistance regions 113 to 115. A region closer to B than the gate electrode 130 is the low resistance region 113. A region closer to A than the gate electrode 140 is the low resistance region 115. A region between the gate electrode 130 and the gate electrode 140 is the low resistance region 114.

The opening 171 is a region that overlaps the semiconductor layer 110 in a plan view and is arranged in the vicinity of an end portion close to B. The electrode 150 is arranged in a region that overlaps the opening 171 in a plan view. The opening 172 is a region that overlaps the semiconductor layer 110 in a plan view and is arranged in the vicinity of an end portion close to A. The electrode 160 is arranged in a region that overlaps the opening 172 in a plan view.

The semiconductor layer 210 has a longitudinal direction in the direction D1 similar to the semiconductor layer 110. The semiconductor layer 210 overlaps the semiconductor layer 110 in a plan view. Specifically, a pattern of the semiconductor layer 210 is positioned inside a pattern of the semiconductor layer 110 in a plan view. That is, all of the pattern outer edges of the semiconductor layer 210 are surrounded by the pattern outer edges of the semiconductor layer 110. The gate electrode 230 crosses the semiconductor layer 210 in the direction D2.

A region of the semiconductor layer 210 that overlaps the gate electrode 230 in a plan view is the channel region 211. On the other hand, a region of the semiconductor layer 210 that does not overlap the gate electrode 230 in a plan view is the low resistance regions 213 and 214. A region closer to B than the gate electrode 230 is the low resistance region 213. A region closer to A than the gate electrode 230 is the low resistance region 214.

The gate electrode 230 overlaps the gate electrode 130 in a plan view. Specifically, a pattern of the gate electrode 230 is positioned inside a pattern of the gate electrode 130 in a plan view. At least in a region overlapping the semiconductor layer 110 in a plan view, the pattern of the gate electrode 230 is positioned inside the pattern of the gate electrode 130. On the other hand, the gate electrode 230 does not overlap the gate electrode 140 in a plan view. In a region between the opening 171 and the opening 172, the gate electrode 140 may be arranged in any region other than the channel region 211.

Although not shown in FIG. 1, an opening 231 is arranged in the insulating layer 170 and the gate insulating layer 220 as shown in FIG. 3. The gate electrode 230 is connected to the gate electrode 130 via the opening 231. Since the same voltage is supplied to the gate electrodes 130 and 230, the transistor 200 operates as a dual-gate transistor controlled by a top-gate (the gate electrode 230) and a bottom-gate (the gate electrode 130).

The opening 272 is arranged in a region that overlaps the semiconductor layer 210 in a plan view. The opening 271 is arranged in a region that overlaps the electrode 150 and the semiconductor layer 210 in a plan view. Further, the opening 271 is arranged in a region that overlaps the pattern end of the electrode 150. Since the opening 271 overlaps the pattern end of the electrode 150, the electrode 250 contacts both the electrode 150 and the semiconductor layer 210, as shown in FIG. 1.

### [4. Functions of Semiconductor Device]

As shown in FIG. 1 to FIG. 3, the transistor 100 is a double-gate transistor controlled by the gate electrodes 130 and 140. Since a voltage between the source and the drain adjacent to the gate electrode 130 and a voltage between the source and the drain adjacent to the gate electrode 140 can be reduced by the double-gate structure, a decrease in reliability due to hot carriers or the like can be suppressed. Furthermore, since the electric field strength at each gate end can be reduced by the double-gate structure, it is possible to suppress a leakage current of the transistor 100.

In the direction D1, the electric field generated by the gate electrode 130 in the channel region 211 of the transistor 200 can be made uniform by making the length of the gate electrode 130 greater than the length of the gate electrode 230. In addition, it is possible to suppress the light incident from the substrate 101 side from reaching the semiconductor layer 210.

In order to suppress the decrease in reliability as described above, it is sufficient that the low resistance region 114 is arranged between the gate electrode 130 and the gate electrode 140, so that the length of the gate electrode 140 can be made smaller than the length of the gate electrode 130 in the direction D1. Furthermore, according to the semiconductor device 10, the P-type transistor 100 and the N-type transistor 200 constituting the CMOS circuit can be stacked. In other words, the channel region 111 of the transistor 100 and the channel region 211 of the transistor 200 overlap in a plan view. By providing such features, a circuit size of the semiconductor device 10 can be reduced. In other words, the semiconductor device 10 can suppress a reduction in reliability while reducing the circuit size.

### [5. Material of Each Member of Semiconductor Device 10]

A rigid substrate having light transmittance such as a glass substrate, a quartz substrate, a sapphire substrate, or the like, is used as the substrate 101. In the case where the substrate 101 needs to have flexibility, a substrate containing a resin such as a polyimide substrate, an acryl substrate, a siloxane substrate, or a fluororesin substrate is used as the substrate 101. In the case where the substrate containing a resin is used as the substrate 101, an impurity may be introduced into the resin in order to improve the heat resistance of the substrate 101. In particular, in the case where the semiconductor device 10 is a top-emission display device, the substrate 101 does not need to be transparent, so that an impurity that degrades the transparency of the substrate 101 may be used. In the case where the semiconductor device 10 is used in an integrated circuit other than a display device, a semiconductor substrate such as a silicon substrate, a silicon carbide substrate, and a compound semiconductor substrate, or a substrate that does not have light transmittance such as a conductive substrate such as a stainless substrate is used as the substrate 101.

For example, low-temperature polysilicon, amorphous silicon, or single-crystal silicon is used as the semiconductor layer 110.

A common metal material is used as the conductive layer including the gate electrodes 130, 140, 230 and the electrodes 150, 160, 250 and 260. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and an alloy or compound thereof can be used. The above-described material may be used in a single layer or stacked layer as the conductive layer.

A common insulating material is used as the insulating layer including the gate insulating layers 120, 220 and the insulating layers 102, 170 and 270. For example, an inorganic insulating layer such as silicon oxide (SiOₓ), silicon oxynitride (SiOₓN_{y}), aluminum oxide (AlOₓ), aluminum oxynitride (AlOₓN_{y}), silicon nitride (SiNₓ), silicon nitride oxide (SiNₓO_{y}), aluminum nitride (AlNₓ), and aluminum nitride oxide (AlNₓO_{y}) is used as the insulating layer. The above-described material may be used in a single layer or stacked layer as the insulating layer.

An insulating layer having a function of releasing oxygen by a heat treatment may be used as the insulating layers 170, 270. That is, an oxide insulating layer containing an excessive amount of oxygen may be used as the insulating layers 170, 270. For example, a temperature of the heat treatment in which the insulating layers 170, 270 release oxygen is 600° C. or lower, 500° C. or lower, 450° C. or lower, or 400° C. or lower. That is, for example, the insulating layers 170, 270 release oxygen at a heat treatment temperature performed in the manufacturing process of the semiconductor device 10 in the case where a glass substrate is used as the substrate 101.

An insulating layer with few defects is used as the gate insulating layers 120, 220. For example, in the case where a composition ratio of oxygen in the gate insulating layers 120, 220 and a composition ratio of oxygen in the insulating layer (hereinafter referred to as “other insulating layer”) having the same composition as the gate insulating layers 120, 220 are compared, the composition ratio of oxygen in the gate insulating layers 120, 220 is closer to the stoichiometric ratio than the composition ratio of oxygen in the other insulating layer. Specifically, in the case where silicon oxide (SiOₓ) is used for each of the gate insulating layers 120, 220 and the insulating layers 170, 270, the composition ratio of oxygen in the silicon oxide used as the gate insulating layers 120, 220 is closer to the stoichiometric ratio of silicon oxide as compared with the composition ratio of oxygen in the silicon oxide used as the interlayer insulating layers 170, 270. For example, a layer in which no defects are observed when evaluated by an electron-spin resonance method (ESR) may be used as the gate insulating layers 120, 220.

SiOₓN_{y} and AlOₓN_{y} are a silicon compound and an aluminum compound containing a smaller proportion (x>y) of nitrogen (N) than oxygen (O). SiNₓO_{y} and AlNₓO_{y} are a silicon compound and an aluminum compound containing a smaller proportion (x>y) of oxygen than nitrogen.

A metal oxide having semiconductor properties is used as the oxide semiconductor layer in the case where the oxide semiconductor layer is used as the semiconductor layer 210. For example, an oxide semiconductor containing indium (In), gallium (Ga), zinc (Zn), and oxygen (O) may be used as the semiconductor layer 210. For example, an oxide semiconductor having a composition ratio of In:Ga:Zn:O=1:1:1:4 may be used as the semiconductor layer 210. However, the oxide semiconductor containing In, Ga, Zn and O used in the present embodiment is not limited to the above-described composition. An oxide semiconductor having a composition other than the above may be used as the oxide semiconductor. For example, an oxide semiconductor layer having a higher ratio of In than those described above may be used to improve mobility. On the other hand, in order to increase a bandgap and reduce the influence of light irradiation, an oxide semiconductor layer having a larger ratio of Ga than those described above may be used.

An oxide semiconductor containing two or more metals including indium (In) may be used as the semiconductor layer 210. In this case, in the semiconductor layer 210, the ratio of the indium element to the total amount of metal elements may be 50% or more in atomic ratio. Gallium (Ga), zinc (Zn), aluminum (Al), hafnium (Hf), yttrium (Y), zirconia (Zr), and lanthanoids may be used as the semiconductor layer 210 in addition to indium. Elements other than those described above may be used as the semiconductor layer 210.

Other elements may be added to the oxide semiconductor containing In, Ga, Zn, and O as the semiconductor layer 210, and metal elements such as Al and Sn may be added. In addition to the above oxide semiconductor, an oxide semiconductor (IGO) containing In and Ga, an oxide semiconductor (IZO) containing In and Zn, an oxide semiconductor (ITZO) containing In, Sn, and Zn, and an oxide semiconductor containing In and W may be used as the semiconductor layer 210.

In the case where the ratio of the indium element is large, the oxide semiconductor layer used as the semiconductor layer 210 is easily crystallized. As described above, the oxide semiconductor layer having a polycrystalline structure can be obtained by using a material in which the ratio of the indium element to the total amount of metal elements is 50% or more. The oxide semiconductor layer preferably contains gallium as a metal element other than indium. Gallium belongs to the same Group 13 element as indium. Therefore, the crystallinity of the oxide semiconductor layer is not inhibited by gallium, and the oxide semiconductor layer has a polycrystalline structure.

The oxide semiconductor layer can be formed using a sputtering method. A composition of the oxide semiconductor layer formed by the sputtering method depends on a composition of a sputtering target. Even when the oxide semiconductor layer has a polycrystalline structure, the composition of the sputtering target substantially matches the composition of the oxide semiconductor layer. In this case, a composition of the metal element of the oxide semiconductor layer can be specified based on a composition of the metal element of the sputtering target.

In the case where the oxide semiconductor layer has a polycrystalline structure, the composition of the oxide semiconductor layer may be identified using an X-ray diffraction (XRD) method. Specifically, the composition of the metal element of the oxide semiconductor layer can be specified based on the crystalline structure and the lattice constant of the oxide semiconductor layer obtained by the XRD method. Furthermore, the composition of the metal element of the oxide semiconductor layer can also be identified using a fluorescent X-ray analysis, or Electron Probe Micro Analyzer (EPMA) analysis, or the like. However, the oxygen element contained in the oxide semiconductor layer may not be identified by these methods because the oxygen element varies depending on the sputtering process conditions.

As described above, the oxide semiconductor layer may include an amorphous structure and may include a polycrystalline structure. The oxide semiconductor having a polycrystalline structure can be manufactured using a Poly-OS (Poly-crystalline Oxide Semiconductor) technique described below. In the following explanation, when distinguishing from the oxide semiconductor having an amorphous structure, the oxide semiconductor having a polycrystalline structure may be described as the Poly-OS.

Furthermore, instead of the semiconductor layer 210, a semiconductor other than the oxide semiconductor may be used. In this case, the semiconductor used in place of the oxide semiconductor may be made of a different material or have a different composition from the semiconductor used in the semiconductor layer 110. That is, the transistor 100 has different characteristics from the transistor 200.

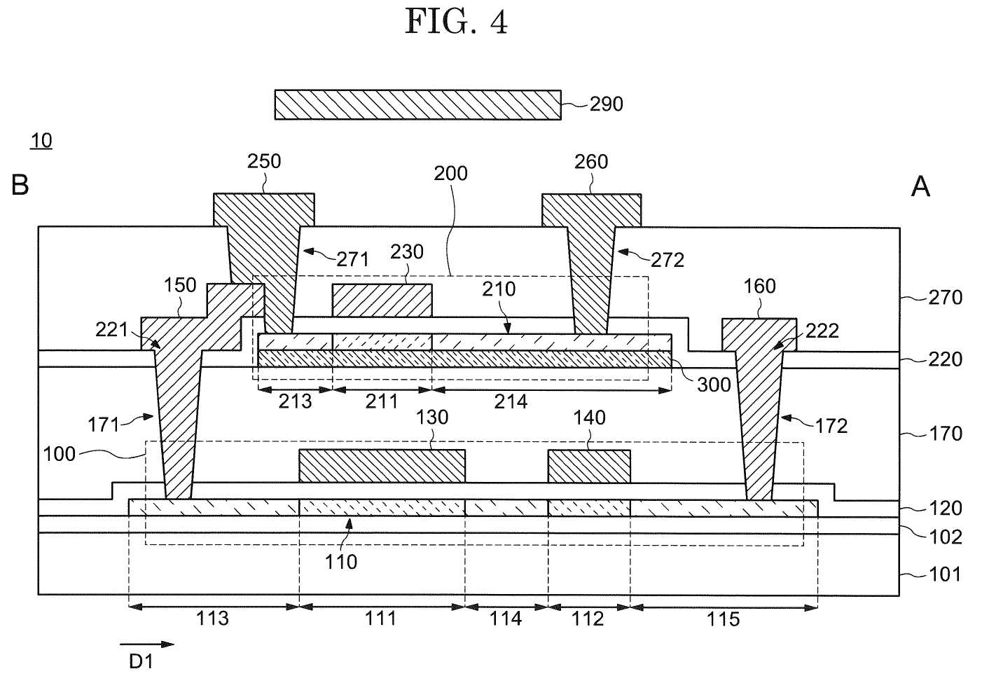

A metal oxide layer 300 may be arranged between the insulating layer 170 and the semiconductor layer 210 (see, FIG. 4). In this case, the metal oxide layer may be in contact with the semiconductor layer 210. The metal oxide containing aluminum as a main component is used as the metal oxide layer. For example, an inorganic insulating layer such as aluminum oxide (AlOₓ), aluminum oxynitride (AlOₓN_{y}), and aluminum oxynitride (AlNₓO_{y}) is used as the metal oxide layer. The “metal oxide layer containing aluminum as a main component” means that the proportion of aluminum contained in the metal oxide layer is 1% or more of the entire metal oxide layer. The proportion of aluminum contained in the metal oxide layer may be 5% or more and 70% or less, 10% or more and 60% or less, or 30% or more and 50% or less of the entire metal oxide layer. The ratio may be a mass ratio or a weight ratio.

### [6. Poly-OS Technique]

The Poly-OS contained in the oxide semiconductor layer used as the semiconductor layer 210 as described above is formed using sputtering and a heat treatment. Here, a method for forming the oxide semiconductor layer will be described.

First, the oxide semiconductor layer is deposited by sputtering. The deposited oxide semiconductor layer has an amorphous structure. In this case, the amorphous structure means a structure in which a long-range ordered structure does not exist and a periodic crystal lattice arrangement is not observed. For example, when the oxide semiconductor layer having an amorphous structure is observed using the XRD method, a certain peak based on the crystalline structure cannot be obtained in the diffractive pattern. The oxide semiconductor layer having an amorphous structure may have a short-range ordered structure in a micro region. However, such an oxide semiconductor layer does not exhibit characteristics of the Poly-OS and can be classified as an oxide semiconductor layer having an amorphous structure.

In the Poly-OS technique, the oxide semiconductor layer is deposited at a low temperature. For example, a temperature of a substrate on which the oxide semiconductor layer is deposited is 150° C. or lower, preferably 100° C. or lower, and more preferably 50° C. or lower. When the temperature of the substrate is high during the deposition of the oxide semiconductor layer, microcrystals are likely to be generated in the oxide semiconductor while depositing the oxide semiconductor. The oxygen partial pressure in a chamber during deposition is 1% or more and 10% or less, preferably 1% or more and 5% or less, and more preferably 2% or more and 4% or less. When the oxygen partial pressure is high, microcrystals are generated in the oxide semiconductor layer due to excess oxygen contained in the oxide semiconductor. On the other hand, under the condition where the oxygen partial pressure is less than 1%, the composition of oxygen in the oxide semiconductor layer becomes uneven, and an oxide semiconductor layer containing a large amount of microcrystals or an oxide semiconductor layer which does not crystallize even when subjected to a heat treatment is formed.

Next, a heat treatment is performed on the oxide semiconductor layer deposited by sputtering. The heat treatment is performed in the atmosphere (air), but an atmosphere (environment) of the heat treatment is not limited to the embodiment. The temperature of the heat treatment is 300° C. or higher and 500° C. or lower, preferably 350° C. or higher and 450° C. or lower. The time of the heat treatment is 15 minutes or more and 120 minutes or less, preferably 30 minutes or more and 60 minutes or less. By performing the heat treatment, the oxide semiconductor layer having an amorphous structure is crystallized to form the oxide semiconductor layer containing the Poly-OS.

### [7. Characteristics of Poly-OS]

Next, the characteristics of the oxide semiconductor layer used as the semiconductor layer 210 and containing the Poly-OS will be described below.

The oxide semiconductor layer has excellent etching resistance. Specifically, the oxide semiconductor layer has a very low etching rate when etching using an etchant during wet etching. This means that the oxide semiconductor layer is hardly etched by the etchant. When the oxide semiconductor layer is etched at about 40° C. using an etchant containing phosphoric acid as a main component, the etching rate is less than 3 nm/min, less than 2 nm/min, or less than 1 nm/min. The proportion of phosphoric acid in the etchant is 50% or more, 60% or more, or 70% or more. The etchant may contain nitric acid and acetic acid in addition to phosphoric acid. The temperature of about 40° C. is a set temperature of a device holding the etchant, and the actual temperature of the etchant is 35° C. or higher and 45° C. or lower.

On the other hand, in the case where the oxide semiconductor layer is etched using the etchant containing phosphoric acid as a main component at a temperature of about 40° C. with respect to an oxide semiconductor layer containing no Poly-OS, for example, the oxide semiconductor layer having an amorphous structure before the heat treatment, the etching rate is 100 nm/min or more.

In the case where the oxide semiconductor layer containing the Poly-OS is etched using 0.5% of a hydrofluoric acid solution at room temperature (for example, about 22° C.), the etching rate is less than 5 nm/min, less than 4 nm/min, or less than 3 nm/min. In this case, the room temperature is 25° C.±5° C. The actual temperature of the etchant at this time is 20° C. or higher and 30° C. or lower.

On the other hand, in the case where the oxide semiconductor layer containing no Poly-OS is etched using 0.5% of the hydrofluoric acid solution at room temperature, the etching rate is 15 nm/min or more.

Here, an embodiment of an etching rate evaluation for the oxide semiconductor layer is shown in Table 1. Table 1 shows the etching rates for a mixed acid etching solution and 0.5% of the hydrofluoric acid solution for each of the prepared samples. “Mixed acid AT-2F (product name)” manufactured by Rasa Industries, Ltd. was used as the mixed acid etching solution. The proportion of phosphoric acid in the mixed acid etching solution is about 65%. When each sample was etched, the temperature of the mixed acid etching solution was about 40° C. and the temperature of 0.5% of the hydrofluoric acid solution was room temperature. In Table 1, Sample 1 is the oxide semiconductor layer containing the Poly-OS, Sample 2 is the oxide semiconductor layer having an amorphous structure before the heat treatment, and Sample 3 is an oxide semiconductor layer containing indium gallium zinc oxide (IGZO) with an indium ratio of less than 50%.

TABLE 1

| | |
|---|---|
| Mixed acid | 0.5% hydrofluoric |
| etching solution | acid solution |

| | | | | |
|---|---|---|---|---|
| Sample 1 | <0.1 | nm/min | <2 | nm/min |
| Sample 2 | 111 | nm/min | >18 | nm/min |

| | | | |
|---|---|---|---|
| Sample 3 | 162 | nm/min | — |

As shown in Table 1, Sample 1 (the oxide semiconductor layer containing the Poly-OS) is hardly etched by the mixed acid etching solution, and only 2 nm/min is etched using 0.5% of the hydrofluoric acid solution. With respect to the mixed acid etching solution, the etching rate of Sample 1 is 1/100 or less of the etching rate of Sample 2 (the oxide semiconductor layer having the amorphous structure before the heat treatment). With respect to 0.5% of the hydrofluoric acid solution, the etching rate of Sample 1 is about 1/10 or less of the etching rate of Sample 2. With respect to the mixed acid etching solution, the etching rate of Sample 1 is 1/100 or less of the etching rate of Sample 3 (the oxide semiconductor layer containing IGZO with an indium ratio of less than 50%). That is, Sample 1 has significantly better etching resistance than Sample 2 and Sample 3.

Such excellent etching resistance of the oxide semiconductor layer containing Poly-OS is a property that cannot be obtained in the oxide semiconductor having a polycrystalline structure manufactured by the conventional process at 500° C. or lower. Although the detailed mechanism for the excellent etching resistance of the oxide semiconductor layer containing the Poly-OS is unclear, the Poly-OS is considered to have a polycrystalline structure different from that of the conventional one.

As discussed above, the etching rate of the oxide semiconductor layer containing the Poly-OS to the etchant is very low. Therefore, it is very difficult to pattern the oxide semiconductor layer. Therefore, in the case where an island-shaped oxide semiconductor layer is formed, the oxide semiconductor layer having an amorphous structure before the heat treatment is patterned into an island shape, and thereafter, the oxide semiconductor layer patterned into the island shape is crystallized by performing the heat treatment. As a result, the island-shaped oxide semiconductor layer containing the Poly-OS is formed.

### [8. Method for Manufacturing Semiconductor Device 10]

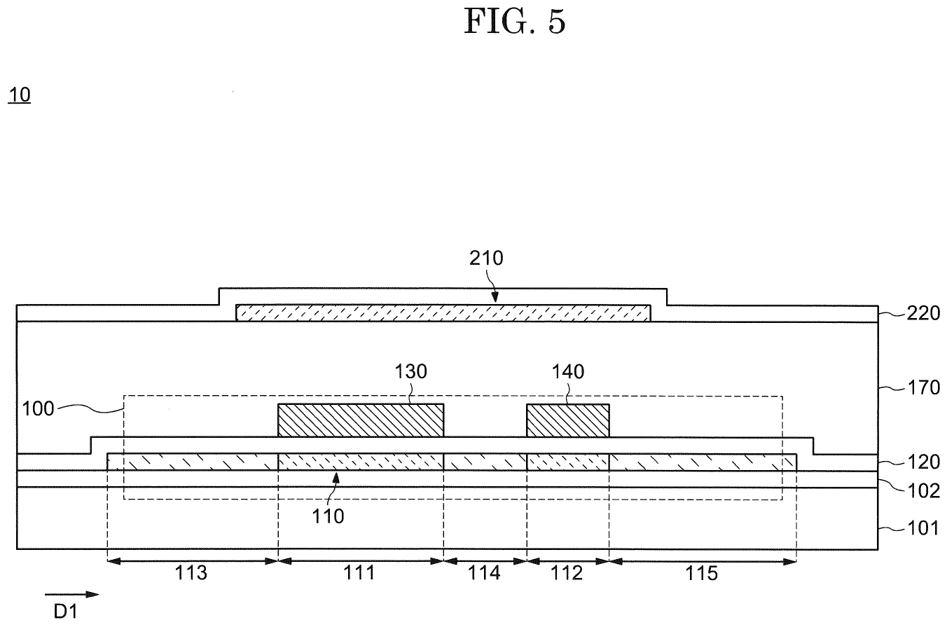

A method for manufacturing a semiconductor device according to an embodiment of the present invention will be described with reference to FIG. 5 to FIG. 8. FIG. 5 to FIG. 8 are cross-sectional views illustrating a method for manufacturing a semiconductor device according to an embodiment of the present invention. In the method for manufacturing the semiconductor device 10 described below, a configuration in which polysilicon is used as the semiconductor layer 110 and an oxide semiconductor (Poly-OS) is used as the semiconductor layer 210 will be described.

As shown in FIG. 5, first, a semiconductor layer made of the insulating layer 102 and polysilicon is formed on the substrate 101, and the semiconductor layer is processed by a photolithography process to form the semiconductor layer 110. Next, the gate insulating layer 120 is formed on the insulating layer 102 and the semiconductor layer 110. Next, a conductive layer is formed on the gate insulating layer 120, and the conductive layer is processed by the photolithography process to form the gate electrodes 130 and 140 overlapping the semiconductor layer 110.

Next, an impurity is implanted into the semiconductor layer 110 via the gate insulating layer 120 using the gate electrodes 130 and 140 as masks. Implantation of the impurity forms the channel regions 111 and 112 and the rest of the low resistance regions 113 to 115. In the case where the transistor 100 is the P-type transistor, boron is used as the impurity. On the other hand, in the case where the transistor 100 is the N-type transistor, phosphorus is used as the impurity.

Next, the insulating layer 170 is formed on the gate insulating layer 120 and the gate electrodes 130 and 140. Next, an oxide semiconductor layer is formed on the insulating layer 170, and the oxide semiconductor layer is processed by the photolithography process to form the semiconductor layer 210. Next, the gate insulating layer 220 is formed on the insulating layer 170 and the semiconductor layer 210.

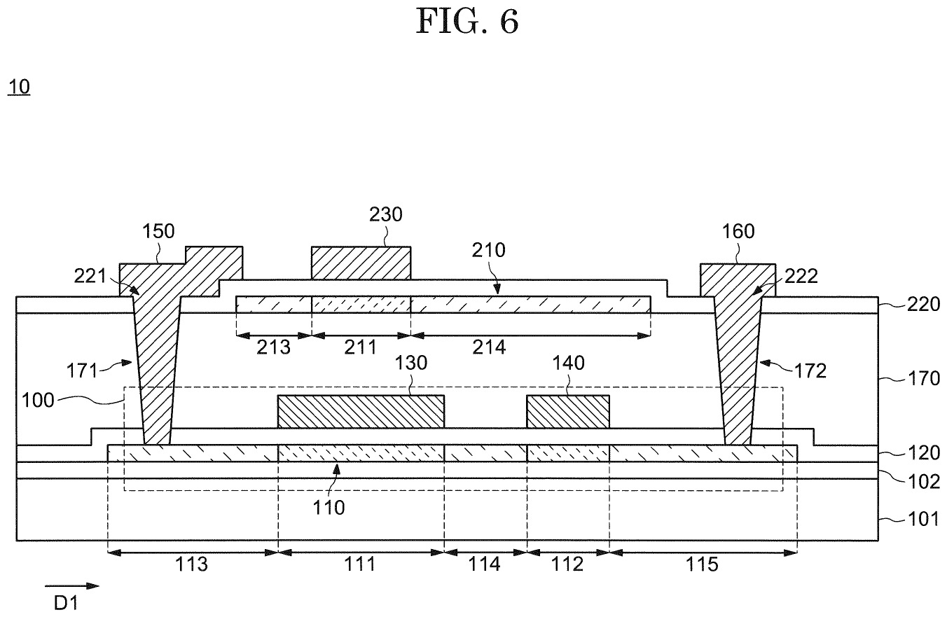

As shown in FIG. 6, the gate insulating layer 220 and the insulating layer 170 are processed by the photolithography process to form the openings 171 and 221 that reach a drain region (the low resistance region 113) of the semiconductor layer 110, and the openings 172 and 222 that reach a source region (the low resistance region 115) of the semiconductor layer 110. Next, a conductive layer is formed on the gate insulating layer 220 and inside the openings 171, 172, 221, and 222. The formed conductive layer is processed by the photolithography process to form the electrodes 150 and 160 and the gate electrode 230.

Next, an impurity is implanted into the semiconductor layer 210 via the gate insulating layer 220 using the gate electrode 230 as a mask. Implantation of the impurity forms the channel region 211 and the low resistance regions 213 and 214. A method for forming the low resistance regions 213 and 214 will be described in detail later.

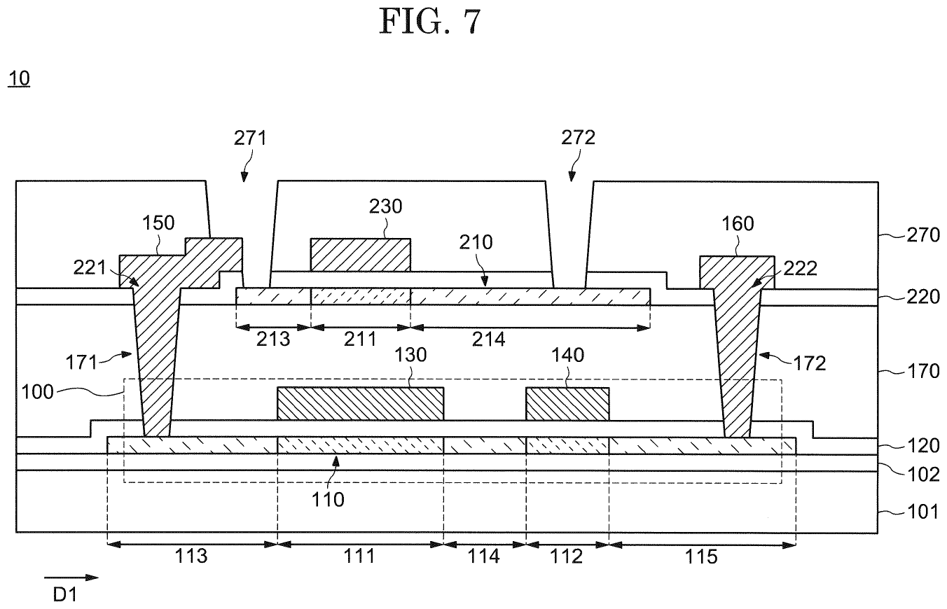

As shown in FIG. 7, the insulating layer 270 covering the electrodes 150 and 160 and the gate electrode 230 is formed on the gate insulating layer 220. The gate insulating layer 220 and the insulating layer 270 are processed by the photolithography process to form the openings 271 and 272 that reach a drain region (the low resistance region 213) and a source region (the low resistance region 214) of the semiconductor layer 210.

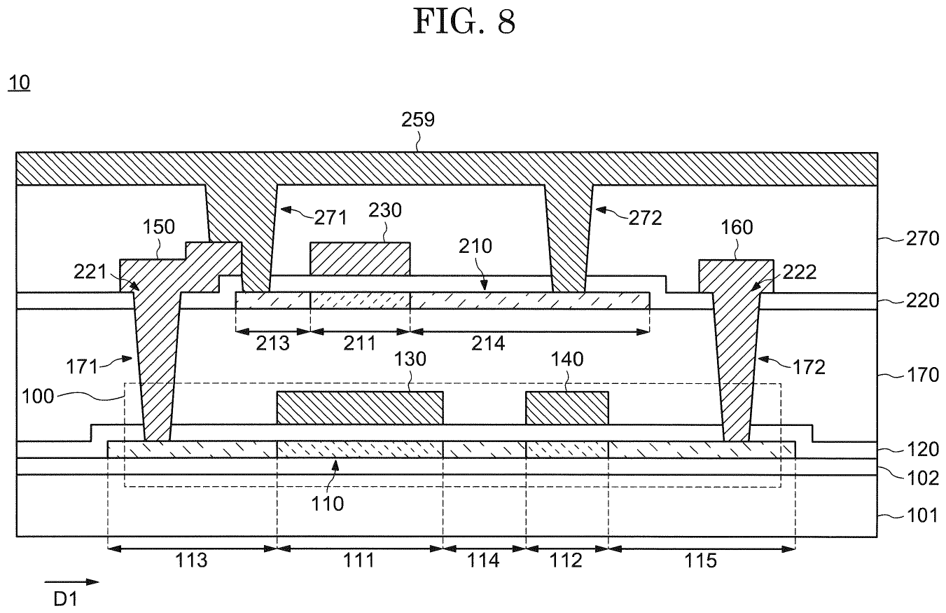

As shown in FIG. 8, a conductive layer 259 is formed on the insulating layer 270 and inside the openings 271 and 272. The formed conductive layer 259 is processed by the photolithography process to form the electrodes 250 and 260 shown in FIG. 1.

### [9. Method for Forming Low Resistance Regions 213 and 214]

A method for forming the drain region (the low resistance region 213) and the source region (the low resistance region 214) of the semiconductor layer 210 will be described with reference to FIG. 6. As shown in FIG. 6, ion implantation is performed on the semiconductor layer 210 in a state where the gate insulating layer 220 and the gate electrode 230 are formed on the semiconductor layer 210. For example, boron (B) as an impurity element is implanted into the semiconductor layer 210 by the ion implantation. However, other impurity elements such as phosphorus (P) may be implanted into the semiconductor layer 210 instead of boron.

In a region where the gate electrode 230 is not arranged, the impurity element passes through the gate insulating layer 220 and reaches the semiconductor layer 210. However, since the impurity element is blocked by the gate electrode 230 in a region (channel region 211) where the gate electrode 230 is arranged, the impurity element does not reach the semiconductor layer 210.

By the ion implantation described above, the low resistance regions 213 and 214 into which the impurity element is implanted are formed in the semiconductor layer 210. In the semiconductor layer 210 in the low resistance regions 213 and 214, since an oxygen vacancy is formed by the implantation of the impurity element, the resistance of the semiconductor layer 210 in the region is reduced. In addition, in the oxide semiconductor layer containing Poly-OS, the oxide semiconductor layers in the low resistance regions 213 and 214 into which the impurity element is implanted may have crystallinity. This is also one of the characteristics of Poly-OS. In this case, the crystal structure of each of the oxide semiconductor layers in the low resistance regions 213 and 214 is the same as the crystal structure of the oxide semiconductor layer in the channel region 211.

In the above manufacturing method, a manufacturing method in which Poly-OS is used as the semiconductor layer 210 has been exemplified, but the manufacturing method of the semiconductor device 10 is not limited to the above method. For example, a manufacturing method in which an oxide semiconductor having an amorphous structure is formed as the semiconductor layer 210 may be used.

Each of the embodiments described above as an embodiment of the present invention can be appropriately combined and implemented as long as no contradiction is caused. Furthermore, the addition, deletion, or design change of components, or the addition, deletion, or condition change of processes as appropriate by those skilled in the art based on each embodiment are also included in the scope of the present invention as long as they are provided with the gist of the present invention.

Furthermore, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
a first semiconductor layer;
a first gate electrode facing the first semiconductor layer;
a second gate electrode facing the first semiconductor layer and supplied with a same voltage as the first gate electrode;
a first gate insulating layer between the first semiconductor layer and the first gate electrode, and between the first semiconductor layer and the second gate electrode;
a second semiconductor layer sandwiching the first gate electrode with the first semiconductor layer;
a third gate electrode facing the second semiconductor layer on an opposite side to the first gate electrode with respect to the second semiconductor layer, and overlapping the first gate electrode in a plan view; and
a second gate insulating layer between the second semiconductor layer and the third gate electrode.

2. The semiconductor device according to claim 1, wherein the second semiconductor layer includes an oxide semiconductor.

3. The semiconductor device according to claim 1, wherein the second gate electrode does not overlap the third gate electrode in a plan view.

4. The semiconductor device according to claim 3, further comprising:
a first electrode connected to the first semiconductor layer in a first region; and
a second electrode connected to the first semiconductor layer in a second region on an opposite side to the first electrode with respect to the first gate electrode and the second gate electrode,
wherein the first gate electrode and the second gate electrode are separated in a cross-sectional view along a line connecting the first region and the second region.

5. The semiconductor device according to claim 4, wherein the first gate electrode is connected to the second gate electrode in a region not overlapping the first semiconductor layer in a plan view.

6. The semiconductor device according to claim 5, further comprising:
a first electrode connected to the first semiconductor layer in a first region; and
a second electrode connected to the first semiconductor layer in a second region on the opposite side to the first electrode with respect to the first gate electrode and the second gate electrode,
wherein a length of the second gate electrode is smaller than a length of the first gate electrode in a first direction connecting the first region and the second region.

7. The semiconductor device according to claim 6, wherein the first gate electrode and the second gate electrode are arranged in a same layer.

8. The semiconductor device according to claim 1, further comprising:
a first electrode connected to the first semiconductor layer in a first region; and
a second electrode connected to the first semiconductor layer in a second region on an opposite side to the first electrode with respect to the first gate electrode and the second gate electrode,
wherein a length of the first gate electrode is larger than a length of the third gate electrode in a first direction connecting the first region and the second direction in a cross-sectional view along a line connecting the first region and the second region.

9. The semiconductor device according to claim 8, further comprising:
a third electrode connected to the second semiconductor layer in a third region; and
a fourth electrode connected to the second semiconductor layer in a fourth region on an opposite side to the third electrode with respect to the third gate electrode,
wherein
different voltages are supplied to the second electrode and the fourth electrode, and
the first electrode and the third electrode are electrically connected.

10. The semiconductor device according to claim 8, wherein the first electrode and the third gate electrode are arranged in the same layer.
